(19) United States
(12) Patent Application Publication
(10) Pub. No.: US 2026/0344079 A1
(43) Pub. Date: Oct. 29, 2026

(54) IMAGE SENSING DEVICE AND METHOD FOR MANUFACTURING THE SAME

(71) Applicant: SK hynix Inc., Icheon-si (KR)

(72) Inventor: Woo Yung JUNG, Icheon-si (KR)

(21) Appl. No.: 19/380,807

(22) Filed: Nov. 5, 2025

(30) Foreign Application Priority Data
Apr. 23, 2025 (KR) 10-2025-0053232

(51) Int. Cl. H10F 39/00

(52) U.S. Cl. CPC H10F 39/8063; H10F 39/024; H10F 39/8053

(57) ABSTRACT

An image sensing device includes a semiconductor substrate including a pixel region and a peripheral region located outside the pixel region; a first metalens layer disposed over the semiconductor substrate in the pixel region, and configured to include first nano-posts and a first air layer disposed between the first nano-posts; a second metalens layer disposed over the first metalens layer, and configured to include second nano-posts and a second air layer disposed between the second nano-posts; a lens support layer disposed between the first metalens layer and the second metalens layer, and configured to extend from the pixel region to the peripheral region; and a peripheral support layer disposed below the lens support layer in the peripheral region, and configured to support the lens support layer.

### CROSS-REFERENCE TO RELATED APPLICATION

This patent document claims the priority and benefits of Korean patent application No. 10-2025-0053232, filed on Apr. 23, 2025, which is incorporated by reference in its entirety as part of the disclosure of this patent document.

### TECHNICAL FIELD

The technology and implementations disclosed in this patent document generally relate to an image sensing device including one or more metalenses.

### BACKGROUND

Meta-optics refers to a field of optical technology that implements new optical characteristics in controlling or manipulating light that cannot be easily implemented with existing materials or convention optical devices such as optical lenses with curved surfaces by using nanostructures with a scale smaller than a wavelength of light.

An image sensor is a device that includes image sensing pixels that convert an optical image into electrical pixel signals. In some implementations of such an image sensor, each pixel of the image sensor may include a microlens for receiving incident light and a color filter for optically filtering light at a desired wavelength or spectral range for sensing while rejecting light components at other wavelengths. As pixels are increasingly manufactured in ultra-fine sizes according to the demand for high-resolution cameras in certain applications, the sizes of microlenses and color filters of the pixels decrease and this decrease in size reduces the optical aperture for receiving light, resulting in a decrease in luminous efficiency in the image sensor.

As an alternative to the limitations of the above conventional technologies, research on metalenses applicable to image sensors based on meta-optics is being actively conducted.

### SUMMARY

Various embodiments of the disclosed technology relate to an image sensing device capable of ameliorating degradation of quantum efficiency (QE) due to oblique incident light and improving the structural stability of metalenses.

In accordance with an embodiment of the disclosed technology, an image sensing device may include: a semiconductor substrate including a pixel region and a peripheral region located outside the pixel region; a first metalens layer disposed over the semiconductor substrate in the pixel region, and configured to include first nano-posts and a first air layer disposed between the first nano-posts; a second metalens layer disposed over the first metalens layer, and configured to include second nano-posts and a second air layer disposed between the second nano-posts; a lens support layer disposed between the first metalens layer and the second metalens layer, and configured to extend from the pixel region to the peripheral region; and a peripheral support layer disposed below the lens support layer in the peripheral region, and configured to support the lens support layer.

In accordance with another embodiment of the disclosed technology, a method for manufacturing an image sensing device may include: forming a first sacrificial layer over a semiconductor substrate in a pixel region and a peripheral region located outside the pixel region; forming first nano-posts within the first sacrificial layer of the pixel region; forming a first support layer on the first sacrificial layer and the first nano-posts in the pixel region and the peripheral region; forming through-holes in the first support layer to expose a portion of the first sacrificial layer in the pixel region; removing the portion of the first sacrificial layer in the pixel region through the through-holes while maintaining a portion of the first sacrificial layer in the peripheral region; forming a second support layer that overlaps the first support layer and fills the through-holes of the first support layer; and forming second nano-posts on the second support layer.

The above and other features, embodiments and examples for implementing the disclosed technology are described in greater detail below with reference to accompanying drawings.

### BRIEF DESCRIPTION OF THE DRAWINGS

FIG. 1 is a plan view illustrating an example of a planar structure of an image sensing device according to an embodiment of the disclosed technology.

FIG. 2 is a cross-sectional view illustrating an example of the structure vertically taken along the line X-X’ of FIG. 1 according to an embodiment of the disclosed technology.

FIGS. 3-15 are cross-sectional views illustrating example methods for forming the structure of FIG. 2 according to an embodiment of the disclosed technology.

### DETAILED DESCRIPTION

This patent document provides implementations and examples of an image sensing device including one or more metalenses that may be used to substantially address one or more technical or engineering issues and mitigate limitations or disadvantages encountered in some other image sensing devices. Some implementations of the disclosed technology suggest examples of an image sensing device capable of ameliorating degradation of quantum efficiency (QE) affected by oblique incident light and improving the structural stability of metalenses. In recognition of the issues above, the disclosed technology can be implemented to provide various features in image sensing devices that can ameliorate degradation of quantum efficiency (QE) with respect to oblique incident light of the image sensing device to which metalenses are applied and additionally improve structural stability of the metalenses.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

Hereinafter, various embodiments will be described with reference to the accompanying drawings. However, it should be understood that the disclosed technology is not limited to specific embodiments, but may be implemented by various modifications, equivalents and/or alternatives of the embodiments. The embodiments of the disclosed technology may provide a variety of effects capable of being directly or indirectly recognized through the disclosed technology.

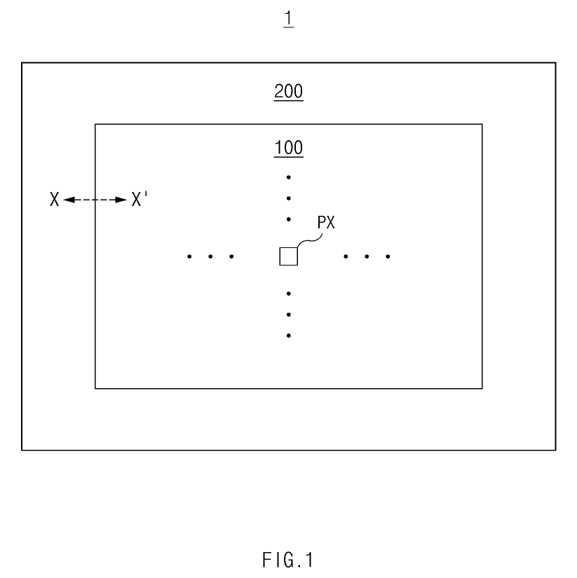

FIG. 1 is a plan view illustrating an example of a planar structure of an image sensing device according to an embodiment of the disclosed technology.

Referring to FIG. 1, the image sensing device 1 may include a pixel region 100 and a peripheral region 200 outside the pixel region 100.

The pixel region 100 may be disposed at the center of the image sensing device 1, and may include a plurality of unit pixels (PXs) supported by a semiconductor substrate and arranged in a two-dimensional (2D) matrix structure (for example, arranged consecutively in a first direction and a second direction perpendicular to the first direction). Each of the plurality of unit pixels (PX) may include a photoelectric conversion element (for example, a photodiode PD) that converts incident light into an electrical signal within the semiconductor substrate. In addition, the plurality of unit pixels (PXs) may include pixel transistors for reading out electrical signals generated by the photoelectric conversion elements.

The pixel region 100 may include a metalens layer formed over the semiconductor substrate to separate incident light by color. For example, the metalens layer may include three-dimensional (3D) nanostructures (e.g., nano-posts) having a scale smaller than a wavelength of light.

In the metalens, an air layer may be formed between adjacent nano-posts, and the nano-posts may be formed in a multilayer structure. A support layer may be formed between the stacked nano-posts to support the nano-posts of an upper layer. The support layer may be formed to extend from the pixel region 100 to the peripheral region. In some implementations, the nano-posts may be formed only in the pixel region 100 and may not be formed in the peripheral region 200. A detailed structure of the metalens layer will be described later in more detail with reference to the attached drawings.

The peripheral region 200 may represent a region located outside the pixel region 100. The peripheral region 200 may be formed to surround the pixel region 100 in some implementations. The peripheral region 200 may include a light blocking layer to prevent incident light from reaching the semiconductor substrate. The peripheral region 200 may include a pad region in which conductive pads are formed for providing electrical connections between the image sensing device and external devices.

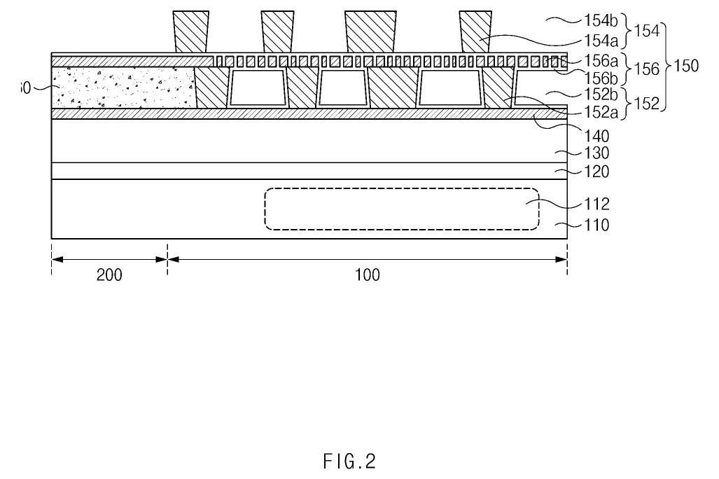

FIG. 2 is a cross-sectional view illustrating an example of the structure vertically taken along the line X-X’ of FIG. 1 according to an embodiment of the disclosed technology.

Referring to FIG. 2, the image sensing device 1 may include a substrate 110, a color filter layer 120 over the substrate 110, an overcoating layer 130 over the color filter layer 120, an etch stop layer 140 over the overcoating layer 130, a metalens layer 150, and a peripheral support layer 160.

The substrate 110 may include a semiconductor substrate having a first surface and a second surface facing or opposite to the first surface. The first surface is a surface upon which light is incident to, and is received by, the image sensing device 1, and the color filter layer 120, the overcoating layer 130, the etch stop layer 140, and the metalens layer 150 may be formed over the first surface of the substrate 110. The semiconductor substrate 110 may be in a monocrystalline state, and may include a silicon-containing material. The semiconductor substrate 110 may include a pixel region 100 and a peripheral region located outside the pixel region 100. The semiconductor substrate 110 of the pixel region 100 may include the photoelectric conversion elements 112 that can perform conversion of incident light received through the first surface, resulting in formation of photocharges.

The color filter layer 120 may include a plurality of color filters arranged to respectively correspond to the unit pixels so that each color filter filters the incident light to each unit pixel to allow light at a certain wavelength of a color to be received and detected while rejecting light in other wavelengths. The color filters may be arranged in a Bayer pattern or another suitable pattern for capturing coloring information of the incident light. The color filter layer 120 may include a grid structure disposed between the color filters to prevent crosstalk between the color filters.

The overcoating layer 130 may be disposed over the color filter layer 120, and may operate as a planarization layer to remove a step difference between the grid structure and the color filters. The overcoating layer 130 may include a material that is transparent to visible light, for example, a dielectric material (e.g., SiO₂, siloxane-based spin on glass (SOG), etc.) that has a lower refractive index than nanostructures (nano-posts) of the metalens layer 150 and a low absorption rate in the visible spectrum.

The overcoating layer 130 may have a material and thickness that can implement a target refractive index together with the etch stop layer 140. The target refractive index may be a theoretical refractive index that should be allocated to the effective medium disposed between two materials, so that undesired light reflection occurring at an interface between materials with different refractive indices can be minimized.

The etch stop layer 140 may be formed over the overcoating layer 130 and may serve as an etch stop to protect the overcoating layer 130 during the etching process for forming first nano-posts (152a). The etch stop layer 140 may include an ultra-low-temperature oxide (ULTO) layer.

A metalens layer 150 may converge (focus) incident light onto the photoelectric conversion elements 112 supported by the substrate 110. For example, the metalens layer 150 may separate incident light into light beams of different colors at different wavelengths respectively corresponding to color filters arranged in a Bayer pattern, and may focus the separated light beams onto the photoelectric conversion elements 112 of the corresponding unit pixels. Since diffraction or scattering characteristics of light differ depending on wavelengths of light, the metalens layer 150 may use such characteristics to separate the colors of incident light from each other. The transmission direction of the separated light beam may be adjusted to correspond to each wavelength according to the refractive index distribution of the metalens layer 150 and the shape of the nano-posts.

In the example in FIG. 2, the metalens layer 150 may include a first metalens layer 152, a second metalens layer 154, and a lens support layer 156.

The first metalens layer 152 and the second metalens layer 154 may be located in the pixel region 100. The first metalens layer 152 may include first nano-posts (152a) and an air layer (152b) in the space between the first nano-posts (152a). The second metalens layer 154 may include second nano-posts (154a) and an air layer (154b) in the space between the second nano-posts (154a).

Each of the first nano-posts (152a) and each of the second nano-posts (154a) may be formed in a pillar shape having a diameter smaller than a wavelength of incident light. For example, the nano-posts (152a, 154a) may be formed in various pillar shapes such as a cylindrical shape, a polygonal pillar shape, and an elliptical pillar shape. The first air layer (152b) may be formed between the first nano-posts (152a) in the first metalens layer 152, and the second air layer (154b) may be formed between the second nano-posts (154a) in the second metalens layer 154.

The first nano-posts (152a) and the second nano-posts (154a) may be formed of the same material in some implementations. For example, the nano-posts (152a, 154a) may include a high-refractive-index material (e.g., TiO₂). The first nano-posts (152a) and the second nano-posts (154a) may be stacked in a one-to-one correspondence with each other based on the lens support layer 156 interposed therebetween, resulting in formation of a nanostructure of the metalens layer 150. The first nano-posts (152a) and the second nano-posts (154a) may be disposed to partially overlap each other in the vertical direction.

The second nano-posts (154a) may be shifted from the first nano-posts (152a) in correspondence with a chief ray angle (CRA) of incident light. For example, the second nano-posts (154a) located in the center of the pixel region 100 may be located such that central axes of the second nano-posts (154a) can coincide with central axes of the first nano-posts (152a), and the second nano-posts (154a) located in the edge region of the pixel region 100 may be located such that central axes of the second nano-posts 154a can be shifted from the central axes of the first nano-posts 152a in response to the chief ray angle (CRA) in the corresponding region.

The stacked nano-posts (152a, 154a) may have the same shape and dimensions. For example, the first nano-posts (152a) and the second nano-posts (154a) that are stacked to correspond to each other may be formed in a pillar shape having the same diameter and height. Alternatively, the first nano-posts (152a) and the second nano-posts (154a) that are stacked to correspond to each other may have different shapes and sizes (dimensions).

The stacked nano-posts (152a, 154a) may be arranged in a pattern that separates incident light by color and allows the separated light to be focused on the unit pixels of the corresponding color. For example, when the color filters of the unit pixels are arranged in a Bayer pattern, the nano-posts (152a, 154a) may be arranged to have a refractive index distribution capable of forming a phase profile that separates incident light into different light beams of different wavelengths for different colors, e.g., red, green, and blue colors, and allows the separated light beams of different colors to be focused on the unit pixels of the corresponding colors. The above-described refractive index distribution may be formed by the shape and arrangement of the nano-posts (152a, 154a), and may be determined by a difference in refractive index between the nano-posts (152a, 154a) and the materials surrounding the nano-posts (152a, 154a).

The metalens layer 150 according to the present embodiment in FIG. 2 may be formed with a structure in which the plurality of nano-posts (152a, 154a) is stacked, and the second nano-posts (154a) of the upper layer may be shifted to correspond to the CRA, thereby ameliorating deterioration of quantum efficiency (QE) affected by oblique incident light. As in the present embodiment in FIG. 2, when the nano-posts (152a, 154a) are formed with a stacked structure and the second nano-posts (154a) of the upper layer are shifted to correspond to the CRA, quantum efficiency (QE) degradation caused by oblique incident light can be improved more effectively as the heights of the nano-posts (152a, 154a) are reduced. The metalens layer 150 according to the present embodiment may allow the air layers (152b, 154b) to be formed between the nano-posts (152a, 154a), so that a difference in refractive indices between the nanostructure and the surrounding material is larger than the refractive index difference in a design where a material having a higher refractive index than the air layer is formed, thereby relatively lowering the heights of the nano-posts (152a, 154a).

In some implementations, the nano-posts (152a, 154a) may be formed in the pixel region 100, and may not be formed in the peripheral region 200. For example, the nano-posts (152a, 154a) may not be formed anywhere in the peripheral region 200, or may not be formed in a specific region (e.g., a pad region) within the peripheral region 200.

The lens support layer 156 may be disposed over the first nano-posts (152a) and the peripheral support layer 160. For example, the lens support layer 156 may be formed to extend from the pixel region 100 to the peripheral region 200. The lens support layer 156 formed in the pixel region 100 may be disposed between the first nano-posts (152a) and the second nano-posts (154a) and may be supported by the first nano-posts (152a) while supporting the second nano-posts (154a). In addition, the lens support layer 156 formed in the peripheral region 200 may be disposed over the peripheral support layer 160 and may be supported by the peripheral support layer 160.

In a situation where the first nano-posts (152a) and the second nano-posts (154a) are formed in a stacked structure and the second nano-posts (154a) of the upper layer are shifted to correspond to the CRA, if there is no lens support layer 156, some of bottom surfaces of the second nano-posts (154a) are supported by the first nano-posts (152a), but the remaining parts of the bottom surfaces are not supported by the first nano-posts (152a). Under this design without a support layer, when the degree of shifting is large, the second nano-posts (154a) may be undesirably tilted or collapse.

In the present embodiment, since the lens support layer 156 is formed under the second nano-posts (154a), the lens support layer 156 may support the second nano-posts (154a). As a result, the second nano-posts (154a) may be more stably stacked over the first nano-posts (152a).

When the first and second nano-posts (152a, 154a) are formed up to the peripheral region 200, it is difficult to remove the nano-posts (152a, 154a) during an etching process for forming a pad in the peripheral region 200. Therefore, according to the present embodiment, the first and second nano-posts (152a, 154a) may not be formed in the peripheral region 200. For example, the nano-posts (152a, 154a) may not be formed anywhere in the peripheral region 200 or may not be formed in a specific region (e.g., a pad region) in the peripheral region 200.

However, if an air layer 152 is formed under the lens support layer 156 in the same manner as in the pixel region 100 without forming the nano-posts (152a, 154a) in the peripheral region 200, the lens support layer 156 may collapse. In this case, the nano-posts (152a, 154a) formed in the pixel region 100 may also be affected. In the present embodiment, in order to prevent collapse of the lens support layer 156 due to the nano-posts (152a, 154a) that is not formed in the peripheral region 200, the peripheral support layer 160 may be formed over the entirety of the peripheral region 200 without forming an air layer (152b) under the lens support layer 156 in the peripheral region 200.

The lens support layer 156 may include a first support layer (156a) including a plurality of through-holes; and a second support layer (156b) covering a top surface and a bottom surface of the first support layer (156a) while filling the through-holes of the first support layer (156a). The through-holes of the first support layer (156a) may be formed only in the pixel region, and may not be formed in the peripheral region 200. The second support layer (156b) may be formed to extend to side surfaces of the first nano-posts (152a) to cover the side surfaces of the first nano-posts (152a). The second support layer (156b) may be formed to extend to top surface of the etch stop layer 140.

The first support layer (156a) and the second support layer (156b) may be formed of the same material. For example, the first support layer (156a) and the second support layer (156b) may include a low temperature oxide (LTO) layer or an ultra-low-temperature oxide (ULTO) layer. Alternatively, the first support layer (156a) and the second support layer (156b) may be formed of different materials.

The peripheral support layer 160 may be formed in the peripheral region 200 where the first metalens layer 152 is not formed, and may thus support the lens support layer 156. The peripheral support layer 160 may be disposed to cover the entire peripheral region 200. The peripheral support layer 160 may include the same material as the overcoating layer 130. For example, the peripheral support layer 160 may include a dielectric material that has a lower refractive index than the nano-posts (152a, 154a) and a low absorption rate in a visible spectrum.

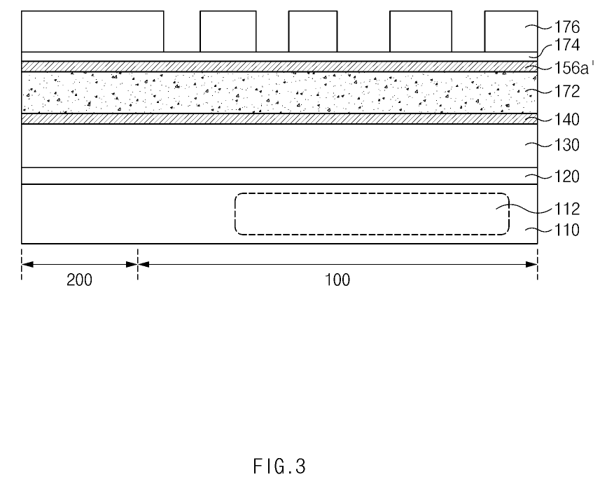

FIGS. 3 to 15 are cross-sectional views illustrating example methods for forming the structure of FIG. 2 according to an embodiment of the disclosed technology.

Referring to FIG. 3, a semiconductor substrate 110 including photoelectric conversion elements 112 may be formed, and a color filter layer 120 including color filters formed to correspond to the photoelectric conversion elements 112 may be formed over the semiconductor substrate 110.

Subsequently, an overcoating layer 130, an etch stop layer 140, a first sacrificial layer 172, a hard mask layer (156a’), and a bottom anti-reflective coating (BARC) layer 174 are sequentially formed over the color filter layer 120 in the pixel region 100 and the peripheral region 200, and then a mask pattern 176 defining a region where the first nano-posts are to be formed may be formed over the bottom anti-reflective coating (BARC) layer 174.

The overcoating layer 130 may include a dielectric material having not only a lower refractive index than the nano-posts but also a low absorption rate in the visible spectrum. The etch stop layer 140 and the hard mask layer (156a’) may include an ultra-low-temperature-oxide (ULTO) layer, and the first sacrificial layer 172 may include the same material as the overcoating layer 130. The mask pattern 176 may include a photoresist pattern. The bottom anti-reflective coating (BARC) layer 174 may be used as an auxiliary layer in a photolithography process for forming the photoresist pattern 176. The bottom anti-reflective coating (BARC) layer 174 may include a silicon oxynitride (SiON) layer.

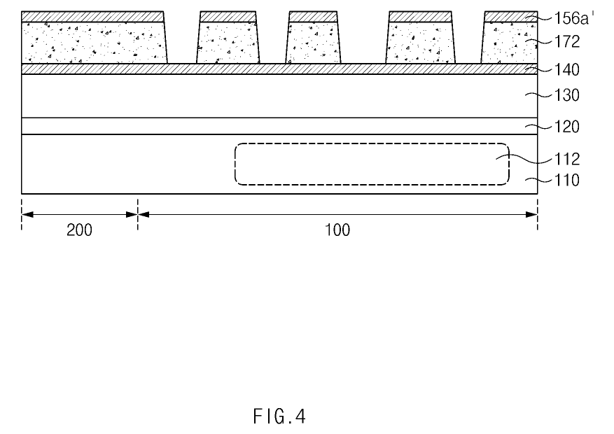

Referring to FIG. 4, the BARC layer 174, the hard mask layer (156a’), and the first sacrificial layer 172 are sequentially etched away by using the mask pattern 176 as an etch mask, and then the mask pattern 176 and the BARC layer 174 are removed, thereby forming trenches in which the first nano-posts are to be formed in the pixel region 100.

Each of the trenches may be formed in a pillar shape. For example, the trenches may be formed in various pillar shapes such as a cylindrical shape, a polygonal pillar shape, an elliptical pillar shape, etc.

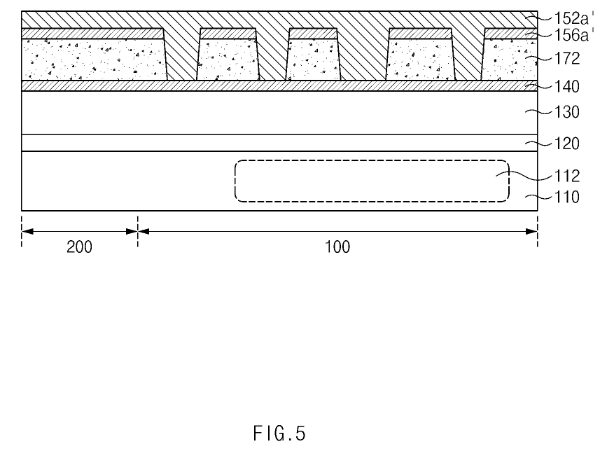

Referring to FIG. 5, a high-refractive-index material (152a’) may be formed in the pixel region 100 and the peripheral region 200 so that the trenches are filled with the high-refractive-index material (152a’). The high-refractive-index material (152a’) may include titanium dioxide (TiO₂), and may be formed through an atomic layer deposition (ALD) process or a spin-on coating process.

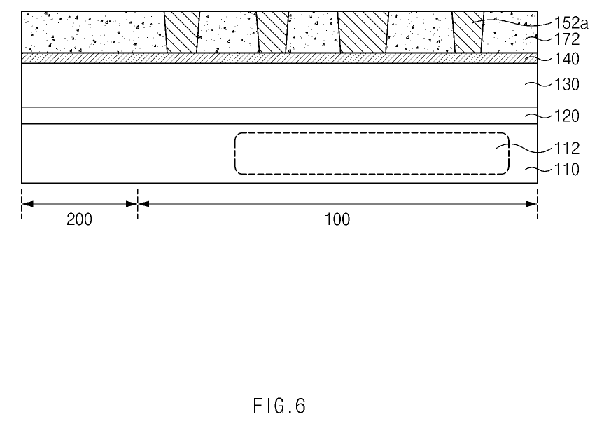

Referring to FIG. 6, the first nano-posts (152a) may be formed by removing the high-refractive-index material (152a’) and the hard mask layer (156a’) so that the first sacrificial layer 172 is exposed. For example, the high-refractive-index material (152a’) and the hard mask layer (156a’) may be removed through a planarization process such as a chemical mechanical polishing (CMP) process.

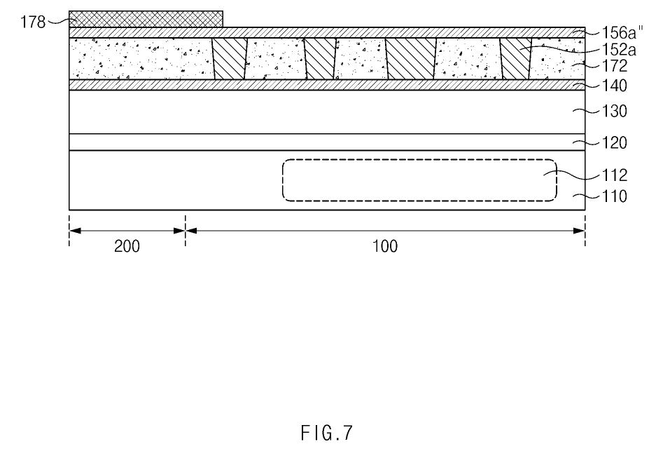

Referring to FIG. 7, the support material layer (156a”) may be formed over the first nano-posts (152a) and the first sacrificial layer 172 in the pixel region 100 and the peripheral region 200. The support material layer (156a”) may include an ultra-low-temperature oxide (ULTO) layer.

Subsequently, a mask pattern 178 covering the peripheral region 200 may be formed over the support material layer (156a”). The mask pattern 178 may be extended to cover a portion of the first nano-posts (152a) located at the outermost portion in the pixel region 100 while covering the peripheral region 200. The mask pattern 178 may include a photoresist pattern.

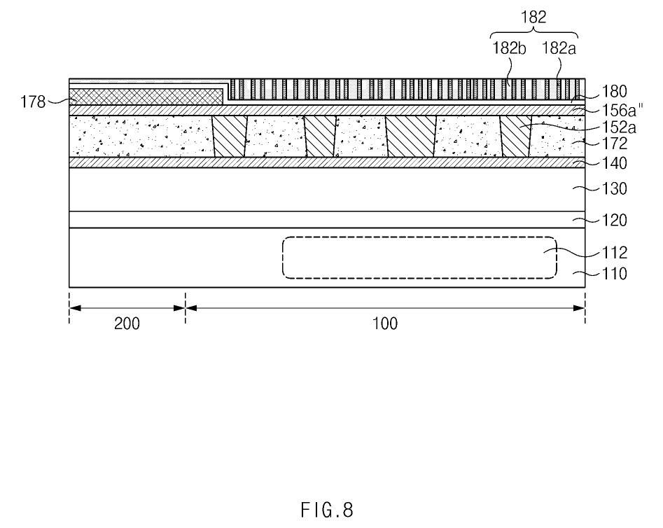

Referring to FIG. 8, a neutral layer 180 of a polymer material and a directed self-assembly (DSA) material layer 182 of a polymer material may be sequentially formed over the support material layer (156a”) and the mask pattern 178.

The neutral layer 180 may be designed to induce pattern formation of the DSA material layer 182. Specifically, the neutral layer 180 may serve to induce phase separation of polymer blocks constituting a block co-polymer in the DSA material layer 182 into block domain portions that are alternately repeated in a cylinder shape or a lamellar shape. The neutral layer 180 may operate as an orientation control layer that controls orientation of the polymer blocks during the phase separation process in which the polymer blocks are rearranged to form block domain portions, thereby causing the block domain portions to be alternately repeated.

The neutral layer 180 may be formed of a material having a similar affinity for each of the polymer block components constituting the block co-polymer. For example, the neutral layer 180 may include a random co-polymer in which different polymer components constituting the block co-polymer are randomly copolymerized. When a polystyrene-polymethyl methacrylate block co-polymer (PS-b-PMMA) is used as a self-aligned block co-polymer, the neutral layer 180 may include a random co-polymer of polystyrene and polymethyl methacrylate (PS-b-PMMA) (i.e., random PS: PMMA (PS-r-PMMA)).

The DSA material layer 182 may include a block co-polymer in which polymer blocks having two or more different structures are covalently bonded to form one polymer. For example, the DSA material layer 182 may include polymethyl methacrylate (PMMA) and polystyrene (PS). The DSA material layer 182 may be coated in a homogeneous phase mixed state using a spin coating method.

Subsequently, DSA patterning may be performed on the DSA material layer 182. For example, an N₂ annealing process may be performed on the DSA material layer 182.

The DSA material layer 182 may be phase-separated into a first polymer block component (182a) and a second polymer block component (182b) by the annealing process. When the DSA material layer 182 includes a block co-polymer, the DSA material layer 182 may be separated into PMMA (polymethyl methacrylate) and PS (polystyrene) by the annealing process. PMMA and PS may be self-aligned in various forms depending on a composition ratio.

The polymer block components that constitute the block co-polymer may have different mixing characteristics and different solubilities due to differences in chemical structures. The polymer components may be immiscibly separated from each other while being intermixed by annealing, and may be reordered, so that the polymer components can be phase-separated from each other.

Forming a microstructure of a specific shape through directed self-assembly of the block co-polymer may be affected by physical and/or chemical characteristics of each block polymer. When a block co-polymer composed of two different polymers is self-assembled, the self-assembled structure of the block co-polymer may be formed in various structures, such as a three-dimensional (3D) cubic and double helix structure, or a two-dimensional (2D) hexagonal packed column structure and a lamellar structure, depending on a volume ratio of each polymer block that constitutes the block co-polymer, the annealing temperature for phase separation, the size of a molecule of the block polymer, and other factors.

Although FIG. 8 illustrates that the DSA material layer 182 is formed in the peripheral region 200 where the mask pattern 178 is formed, other implementations are also possible, and it should be noted that the mask pattern 178 is formed to have a large thickness so that the DSA material layer 182 can be formed only in the pixel region 100 in which the mask pattern 178 is not formed. Alternatively, the DSA material layer 182 may be formed to have a very small thickness over the mask pattern 178, so that DSA patterning may not be performed normally. Accordingly, FIG. 8 illustrates the DSA material layer 182 formed over the mask pattern 178, but the phase-separated appearance of the DSA material layer 182 is not illustrated in FIG. 8.

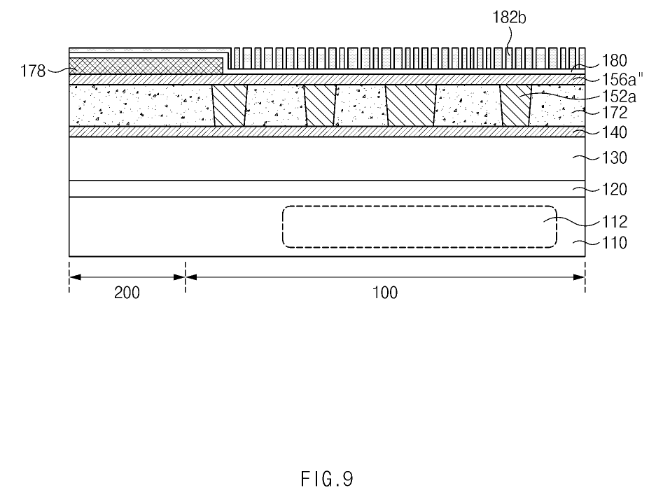

Referring to FIG. 9, the first polymer block component (182a) may be selectively removed from the DSA material layer 182 separated into the first polymer block component (182a) and the second polymer block component (182b).

For example, a metal-containing precursor may be injected into the DSA material layer 182 so that the metal-containing precursor can be selectively coupled (bound) to the first polymer block component (182a). The metal of the metal-containing precursor may include aluminum (Al). The metal-containing precursor may include tetramethylammonium (TMA). For example, TMA may be selectively coupled (bound) to PMMA.

By injecting such a metal-containing precursor, the metal may penetrate into the first polymer block component (182a), so that the first polymer block component (182a) may be modified into the metal-containing first polymer block component. The metal-containing first polymer component may have an etch selectivity with respect to the second polymer block component (182b). The first polymer block component (182a) may be selectively removed using the etch selectivity.

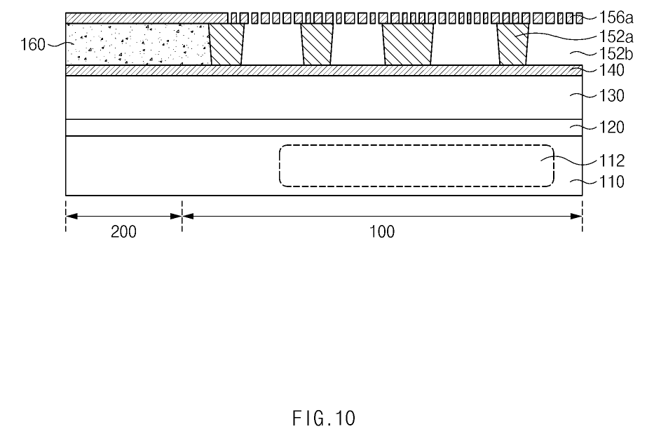

Referring to FIG. 10, the neutral layer 180 and the support material layer (156a”) of the pixel region 100 are etched using a DSA pattern including the second polymer block component (182b) as an etch mask, resulting in formation of through-holes in the support material layer (156a”). When the support material layer (156a”) is etched, the first nano-posts (152a) may not be etched using the etch selectivity.

In the peripheral region 200, as described above, the DSA patterning is not performed normally, so that the DSA pattern is not formed, or even if the DSA pattern is formed, the support material layer (156a”) is not etched due to the mask pattern 178 formed thereunder. In other words, the support material layer (156a”) may be selectively etched only in the pixel region 100 by the mask pattern 178, resulting in formation of through-holes.

Subsequently, the neutral layer 180 and the mask pattern 178 are removed, so that a first support layer (156a) having through-holes formed only in the pixel region 100 may be formed. Accordingly, the first sacrificial layer 172 may be exposed to the outside through the through-holes only in the pixel region 100.

Then, an etching process that selectively removes the first sacrificial layer 172 using the first support layer (156a) having through-holes formed therein as an etch mask may be performed. Through the etching process, the first sacrificial layer 172 in the pixel region 100 is removed and the first sacrificial layer 172 in the peripheral region 200 remains, so that an air layer (152b) may be formed in the space between the first nano-posts (152a) and a peripheral support layer 160 is formed in the peripheral region 200. At this time, an O₂ plasma process may be used for the etching process.

In the pixel region 100, the first sacrificial layer 172 can be removed by the O₂ plasma penetrating into the first sacrificial layer 172 through the through-holes, but in the peripheral region 200 where the through-holes are not formed, the O₂ plasma does not penetrate into the first sacrificial layer 172, so that the first sacrificial layer 172 is not removed and remains, resulting in formation of the peripheral support layer 160.

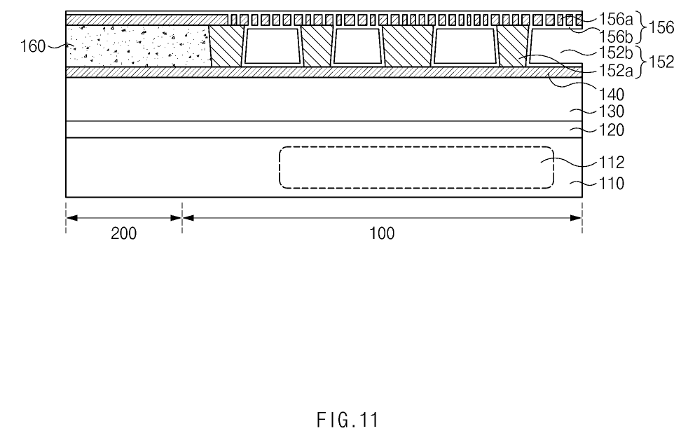

Referring to FIG. 11, an insulation material may be deposited to fill the through-holes of the first supporting layer (156a), resulting in formation of the second supporting layer (156b).

The second support layer (156b) may be formed to cover the top and bottom surfaces of the first support layer (156a) while filling the through-holes of the first support layer (156a). In addition, the second support layer (156b) may be formed to cover the side surfaces of the first nano-posts (152a).

The second support layer (156b) may include the same ultra-low-temperature oxide (ULTO) layer as the first support layer (156a). Alternatively, the second support layer (156b) may be formed of a different material layer from the first support layer (156a) in certain implementations.

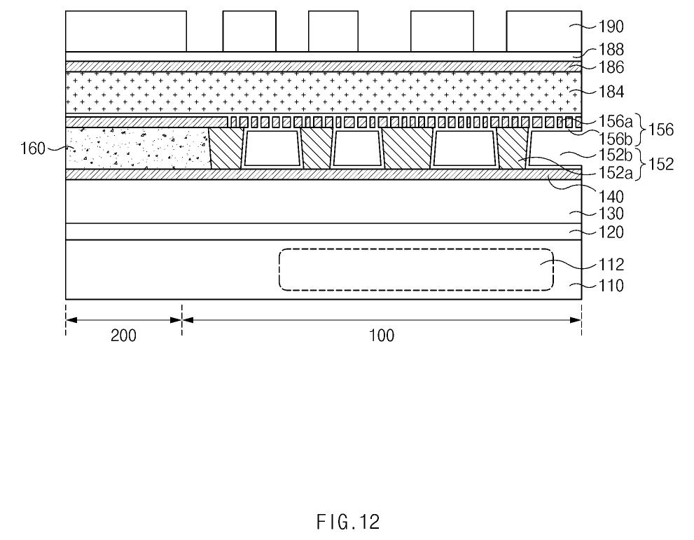

Referring to FIG. 12, a second sacrificial layer 184, a hard mask layer 186, and a bottom anti-reflective coating (BARC) layer 188 are sequentially formed over the second support layer (156b), and then a photoresist pattern 190 defining regions where the second nano-posts are to be formed may be formed over the bottom anti-reflective coating (BARC) layer 188. At this time, the second sacrificial layer 184 may include a carbon-containing SOC (spin on carbon) layer, and the hard mask layer 186 may include an ultra-low-temperature oxide (ULTO) layer. The bottom anti-reflective coating (BARC) layer 188 may be used as an auxiliary layer in a photolithography process for forming the photoresist pattern 190. The bottom anti-reflective coating (BARC) layer 188 may include a silicon oxynitride (SiON) layer.

The open regions of the photoresist pattern 190 may be arranged to correspond to the chief ray angle (CRA) of incident light. For example, the open regions of the photoresist pattern 190 may be located such that central axes of the open regions of the photoresist pattern 190 coincide with the first nano-posts (152a) in the central region of the pixel region 100 and are shifted from the first nano-posts (152a) in the edge region of the pixel region 100.

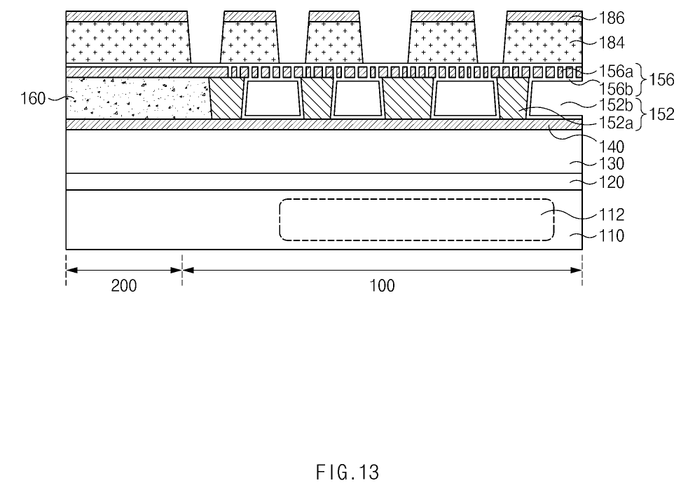

Referring to FIG. 13, a bottom anti-reflection coating (BARC) layer 188, a hard mask layer 186, and a second sacrificial layer 184 are sequentially etched using a photoresist pattern 190 as an etch mask, and then the photoresist pattern 190 and the bottom anti-reflection coating (BARC) layer 188 are removed, so that trenches to be used for formation of second nano-posts can be formed in the pixel region 100.

The trenches may be formed so that the support layer 156 is exposed outside. Each of the trenches may be formed in a pillar shape. For example, the trenches may be formed in various pillar shapes such as a cylindrical shape, a polygonal pillar shape, an elliptical pillar shape, etc.

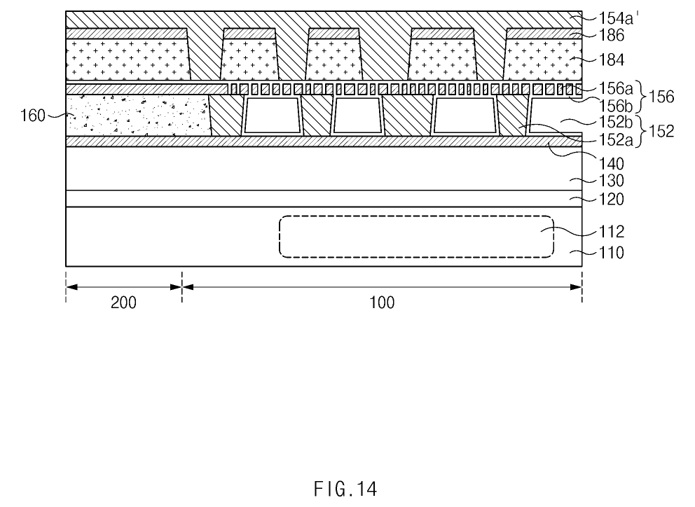

Referring to FIG. 14, a high-refractive-index material (154a’) may be formed in the pixel region 100 and the peripheral region 200 so that the trenches are filled with the high-refractive-index material (154a’). The high-refractive-index material (154a’) may include titanium dioxide (TiO₂), and may be formed through an atomic layer deposition (ALD) process or a spin-on coating process.

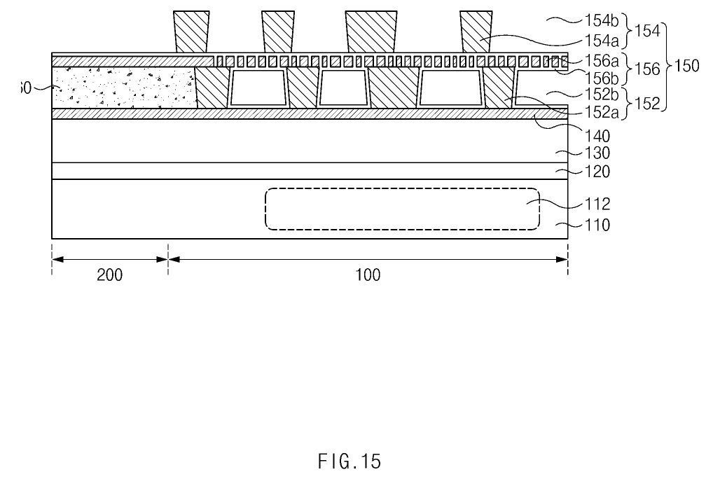

Referring to FIG. 15, the second nano-posts (154a) may be formed by removing the high-refractive-index material (154a’) and the hard mask layer 186 so that the second sacrificial layer 184 is exposed. For example, the high-refractive-index material (154a’) and the hard mask layer 186 may be removed through a planarization process such as a chemical mechanical polishing (CMP) process.

Subsequently, the second sacrificial layer 184 exposed to the outside may be etched and removed, thereby forming an air layer (154b) in the space between the second nano-posts (154a). At this time, the etching process may use the O₂ plasma process.

The air layer (154b) may be formed not only in the pixel region 100 but also in the peripheral region 200.

Although the above-described embodiments have disclosed that the metalens layer 150 includes the nanostructure in which two nano-posts (152a, 154a) are stacked for convenience of description, other implementations are also possible, and for example, three or more nano-posts may be stacked.

As is apparent from the above description, the image sensing device and the method for manufacturing the same according to the embodiments of the disclosed technology can ameliorate degradation of quantum efficiency (QE) with respect to oblique incident light of the image sensing device to which metalenses are applied.

The image sensing device and the method for manufacturing the same according to the embodiments of the disclosed technology can improve structural stability of the metalenses.

The embodiments of the disclosed technology may provide a variety of effects capable of being directly or indirectly recognized through the above-mentioned patent document.

Although a number of illustrative embodiments have been described, it should be understood that various modifications or enhancements of the disclosed embodiments and other embodiments can be devised based on what is described and/or illustrated in this patent document.

What is claimed is:

1. An image sensing device comprising:
a semiconductor substrate including a pixel region and a peripheral region located outside the pixel region;
a first metalens layer disposed over the semiconductor substrate in the pixel region, and configured to include first nano-posts and a first air layer disposed between the first nano-posts;
a second metalens layer disposed over the first metalens layer, and configured to include second nano-posts and a second air layer disposed between the second nano-posts;
a lens support layer disposed between the first metalens layer and the second metalens layer, and configured to extend from the pixel region to the peripheral region; and
a peripheral support layer disposed below the lens support layer in the peripheral region, and configured to support the lens support layer.

2. The image sensing device according to claim 1, wherein:
the peripheral support layer is disposed to cover the entire peripheral region.

3. The image sensing device according to claim 1, wherein:
the peripheral support layer includes a dielectric material having a lower refractive index than a refractive index of the first and second nano-posts.

4. The image sensing device according to claim 1, wherein the lens support layer includes:
a first support layer including a plurality of through-holes; and
a second support layer configured to fill the plurality of through-holes of the first support layer.

5. The image sensing device according to claim 4, wherein:
the second support layer is configured to cover a top surface and a bottom surface of the first support layer.

6. The image sensing device according to claim 5, wherein:
top surfaces of the first nano-posts contact the first support layer; and
bottom surfaces of the second nano-posts contact the second support layer.

7. The image sensing device according to claim 4, wherein:
the second support layer extends to side surfaces of the first nano-posts.

8. The image sensing device according to claim 4, wherein:
the first support layer and the second support layer include a same material layer.

9. The image sensing device according to claim 4, wherein:
each of the first support layer and the second support layer includes an ultra-low-temperature oxide (ULTO) layer.

10. The image sensing device according to claim 1, wherein:
the first nano-posts and the second nano-posts are located such that at least a portion of the first nano-posts and at least a portion of the second nano-post overlap each other in a vertical direction.

11. The image sensing device according to claim 10, wherein:
the second nano-posts are arranged to be shifted from the first nano-posts in response to a chief ray angle (CRA) of incident light.

12. The image sensing device according to claim 1, further comprising:
a color filter layer disposed between the semiconductor substrate and the first metalens layer; and
an over-coating layer disposed between the color filter layer and the first metalens layer.

13. A method for manufacturing an image sensing device comprising:
forming a first sacrificial layer over a semiconductor substrate in a pixel region and a peripheral region located outside the pixel region;
forming first nano-posts within the first sacrificial layer of the pixel region;
forming a first support layer on the first sacrificial layer and the first nano-posts in the pixel region and the peripheral region;
forming through-holes in the first support layer to expose a portion of the first sacrificial layer in the pixel region;
removing the portion of the first sacrificial layer in the pixel region through the through-holes while maintaining a portion of the first sacrificial layer in the peripheral region;
forming a second support layer that overlaps the first support layer and fills the through-holes of the first support layer; and
forming second nano-posts on the second support layer.

14. The method according to claim 13, wherein the forming the through-holes includes:
forming a mask pattern covering the peripheral region on the first support layer;
forming a directed self-assembly (DSA) pattern on the first support layer that is not covered by the mask pattern; and
etching the first support layer using the DSA pattern as an etch mask.

15. The method according to claim 14, wherein the forming the DSA pattern includes:
forming a neutral layer and a DSA material layer in a region where the mask pattern is not formed;
annealing the DSA material layer to separate the DSA material layer into a first polymer block component and a second polymer block component; and
selectively removing the first polymer block component.

16. The method according to claim 13, wherein the removing the first sacrificial layer includes:
performing an O₂ plasma process using the first support layer in which the through-holes are formed, as an etch mask.

17. The method according to claim 13, wherein the removing the first sacrificial layer includes:
forming a first air layer by removing the first sacrificial layer disposed between the first nano-posts.

18. The method according to claim 13, wherein the forming the second support layer includes:
forming the second support layer on a top surface and a bottom surface of the first support layer while filling the through-holes.

19. The method according to claim 13, wherein the forming the second support layer includes:
forming the second support layer to cover side surfaces of the first nano-posts.

20. The method according to claim 13, wherein the forming the second nano-posts includes:
forming a second sacrificial layer on the second support layer;
forming the second nano-posts in the second sacrificial layer; and
forming a second air layer between the second nano-posts by removing the second sacrificial layer.
